(19) United States
(12) Patent Application Publication
(10) Pub. No.: US 2008/0237616 A1
(43) Pub. Date: Oct. 2, 2008

(54) SEMICONDUCTOR LIGHT EMITTING DEVICE AND METHOD FOR MANUFACTURING THE SAME

(75) Inventors: Genichi Hatakoshi, Yokohama-shi (JP); Shinji Saito, Yokohama-shi (JP); Yasushi Hattori, Kawasaki-shi (JP); Sinya Nunoue, Ichikawa-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/923,114

(22) Filed: Oct. 24, 2007

(30) Foreign Application Priority Data
Mar. 27, 2007 (JP) P2007-82000

(51) Int. Cl. H01L 33/00; H01L 21/00

(52) U.S. Cl. 257/94; 438/22; 257/E21.001; 257/E33.001

(57) ABSTRACT

A semiconductor light emitting device, includes an active layer radiating a light having a predetermined wavelength; a first semiconductor layer of a first conductivity type, provided on the active layer. A semiconductor substrate has a first principal surface in contact with the active layer, a second principal surface facing the first principal surface, and side surfaces connected to the second principal surface. Each of the side surfaces has a bevel angle in a range from about 45 degrees to less than 90 degrees with respect to the second principal surface. A second semiconductor layer of a second conductivity type is provided under the active layer. A first electrode is provided under the second semiconductor layer. A distance between the active layer and the first electrode depends on the wavelength and a refractive index of the second semiconductor layer.

### CROSS REFERENCE TO RELATED APPLICATIONS AND INCORPORATION BY REFERENCE

This application is based upon and claims the benefit of priority from prior Japanese Patent Application P2007-082000 filed on Mar. 27, 2007; the entire contents of which are incorporated by reference herein.

### BACKGROUND OF THE INVENTION

1. Field of the Invention

The present invention relates to a semiconductor light emitting device and a method for manufacturing the same.

2. Description of the Related Art

In a semiconductor light emitting device, such as a light emitting diode (LED) and the like, the refractive index of a semiconductor material of the semiconductor light emitting device is greater than air or a resin which is in contact with the semiconductor material. For this reason, total reflection occurs on an interface between the semiconductor material and the air or the resin so as to extremely decrease the light extraction efficiency of the semiconductor light emitting device. In order to increase the light extraction efficiency, various techniques, such as device shape processing, surface texture structure, and a photonic crystal, have been developed.

As one of such techniques, a technique for improving the light extraction efficiency by using interference has been reported (refer to JP-A 2004-207742 (KOKAI)). In a gallium nitride (GaN) based LED, a light output in a vertical direction can be intensified by interference with a reflection light from an electrode of the LED. For example, in the GaN based LED fabricated on a sapphire substrate, the light extraction efficiency from the sapphire substrate to the air is increased or decreased depending on the distance between an active layer serving as a light emitting layer and electrodes provided on a surface of a GaN layer. That is, the light extraction efficiency is increased when the reflection light from the electrode on the surface of the GaN layer and the light emitted in the vertical direction in the GaN layer get a constructive interference with each other. However, as a consequence of the total reflection on an interface between the GaN layer and the sapphire substrate, a value of the light extraction efficiency cannot be increased.

Furthermore, since a sapphire substrate is used, a flip-chip structure is employed, in which both of a p-side electrode and an n-side electrode of the LED are formed on a surface of the GaN layer opposite to the sapphire substrate. As a result, there is a problem in that a package assembly is difficult. Additionally, since the current is forced to flow horizontally in a narrow channel, series resistance between the electrodes also increases.

A conductive GaN substrate may be used instead of the sapphire substrate to provide a structure that enables a current to flow vertically between the electrodes. By using a GaN substrate, it is possible to provide the electrodes on front and back surfaces of the LED and to decrease series resistance between the electrodes. However, when the electrodes are provided on the front and back surfaces, it is impossible to extract a light from portions of the electrodes. Therefore, it is difficult to use the interference effect of a light reflected from the bottom electrode so as to intensify the light in the vertical direction of the LED, as mentioned above. Accordingly, in a typical semiconductor light emitting device, it is difficult to satisfy both requirements of low series resistance and high light extraction efficiency. Thus, it is difficult to achieve a semiconductor light emitting device having high performance.

### SUMMARY OF THE INVENTION

A first aspect of the present invention inheres in a semiconductor light emitting device including an active layer radiating a light having a wavelength λ; a first semiconductor layer of a first conductivity type provided on the active layer, the first semiconductor layer having a first principal surface, a second principal surface and side surfaces, the first principal surface in contact with the active layer, the second principal surface facing the first principal surface, and the side surfaces connected to the second principal surface, each of the side surfaces having a bevel angle in a range from about 45 degrees to less than 90 degrees with respect to the second principal surface; a second semiconductor layer of a second conductivity type provided under the active layer; and a first electrode provided under the second semiconductor layer, wherein a distance d between the active layer and the first electrode depends on the wavelength λ and a refractive index n of the second semiconductor layer.

A second aspect of the present invention inheres in a method for manufacturing a semiconductor light emitting device including growing an active layer on a front surface of a first semiconductor layer having a first conductivity type; growing a second semiconductor layer of a second conductivity type on the active layer; forming a first electrode on the second semiconductor layer; forming a second electrode on a back surface of the first semiconductor layer; and dividing the first and second semiconductor layers into a chip having side surfaces, each of the side surfaces having a bevel angle in a range from about 45 degrees to less than 90 degrees with respect to the back surface, wherein a distance between the active layer and the first electrode depends on a wavelength λ and a refractive index n of the second semiconductor layer.

### BRIEF DESCRIPTION OF THE DRAWINGS

FIG. 1 is a plan view showing an example of a semiconductor light emitting device according to an embodiment of the present invention;

FIG. 2 is a cross sectional view taken on line II-II of the semiconductor light emitting device shown in FIG. 1;

FIG. 3 is a cross sectional view showing an example of a mounted semiconductor light emitting device according to the embodiment of the present invention;

FIG. 4 is a diagram showing a relation of a light extraction efficiency and a distance between the active layer and the first electrode of the semiconductor light emitting device according to the embodiment of the present invention;

FIG. 5 is a diagram showing a relation of a light extraction efficiency and an angle of the side surface of the semiconductor light emitting device according to the embodiment of the present invention;

FIG. 6 is a cross sectional view showing an example of a semiconductor light emitting device of a comparative example;

FIG. 7 is a diagram showing a relation of a light extraction efficiency and a distance between the active layer and the first electrode of the semiconductor light emitting device of the comparative example;

FIG. 8 is a diagram showing an example of a light distribution characteristic in the sapphire substrate of the semiconductor light emitting device of the comparative example;

FIG. 9 is a stereograph of the light distribution characteristic shown in FIG. 8;

FIG. 10 is a diagram showing an example of a light distribution characteristic in the air of the semiconductor light emitting device of the comparative example;

FIG. 11 is a stereograph of the light distribution characteristic shown in FIG. 10;

FIG. 12 is a diagram showing another example of a light distribution characteristic in the sapphire substrate of the semiconductor light emitting device of the comparative example;

FIG. 13 is a stereograph of the light distribution characteristic shown in FIG. 12;

FIG. 14 is a diagram showing another example of a light distribution characteristic in the sapphire substrate of the semiconductor light emitting device of the comparative example;

FIG. 15 is a stereograph of the light distribution characteristic shown in FIG. 14;

FIG. 16 is a diagram showing a relation of a light extraction efficiency and an angle of the side surface of the semiconductor light emitting device of the comparative example;

FIG. 17 is a diagram showing an example of a light distribution characteristic in the semiconductor substrate of the semiconductor light emitting device according to the embodiment of the present invention;

FIG. 18 is a view showing an example of extraction of a light from the semiconductor layer to the resin member of the semiconductor light emitting device according to the embodiment of the present invention;

FIG. 19 is a diagram showing a relation of a light extraction efficiency and an angle of the side surface of the semiconductor light emitting device according to the embodiment of the present invention;

FIG. 20 is a diagram showing a relation of a light extraction efficiency and a number of quantum wells of the semiconductor light emitting device according to the embodiment of the present invention;

FIG. 21 is a cross sectional view showing another example of the semiconductor light emitting device according to the embodiment of the present invention; and

FIGS. 22-25 are cross sectional views showing an example of a manufacturing method of the semiconductor light emitting device according to the embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

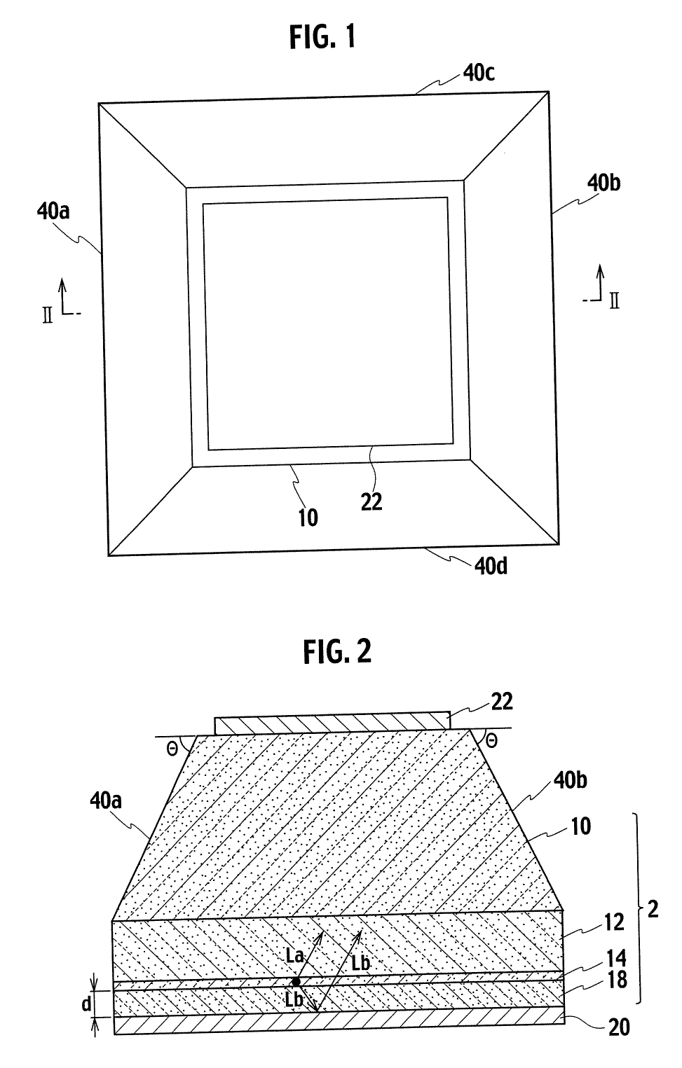

An LED chip (20, 2 and 22) of a semiconductor light emitting device according to an embodiment of the present invention includes a first electrode 20, a semiconductor layer 2, and a second electrode 22, as shown in FIGS. 1, 2. The semiconductor layer 2 includes a first semiconductor layer (10, 12), an active layer 14 and a second semiconductor layer (contact layer) 18. The first semiconductor layer (10, 12) is provided on the active layer 14. The second semiconductor layer 18 is provided under the active layer 14.

The first semiconductor layer (10, 12) includes a semiconductor substrate 10, and a buffer layer 12 on a front surface (first principal surface) of the semiconductor substrate 10. The first electrode 20 is disposed on a front surface of the contact layer 18. The second electrode 22 is disposed on a back surface (second principal surface) of the semiconductor substrate 10 so as to face the first electrode 20 across the semiconductor layer 2. The active layer 14 is a light emitting layer of the semiconductor light emitting device.

For example, for the semiconductor substrate 10, an n-type (first conductivity type) semiconductor substrate, such as a GaN substrate, may be used. For the buffer layer 12, an n-type growth layer, such as a GaN layer, may be used. For the active layer 14, a quantum well (QW) layer, such as indium gallium nitride (InGaN) layers, may be used. For the contact layer 18, a p-type (second conductivity type) growth layer, such as a GaN layer, may be used. For the first electrode 20, a metal, such as silver (Ag), aluminum (Al), gold (Au), and palladium (Pd), and an alloy containing such metal as a main component may be used. For the first electrode 20, Ag, which is a high reflection film material, or a Ag alloy including a metal, such as Pd, rhodium (Rh), Au, copper (Cu), neodymium (Nd), titanium (Ti), magnesium (Mg), zinc (Zn), and In, is desirable. For the second electrode 22, a laminated metal film, such as a Ti/platinum (Pt)/Au film, may be used.

Note that the first conductivity type and the second conductivity type are conductivities opposite to each other. Specifically, if the first conductivity type is n-type, the second conductivity type is p-type, and, if the first conductivity type is p-type, the second conductivity type is n-type. In the following description, for convenience, n-type conductivity is set as the first conductivity type, and p-type conductivity is set as the second conductivity type. However, p-type may be set as the first conductivity type and n-type may be set as the second conductivity type.

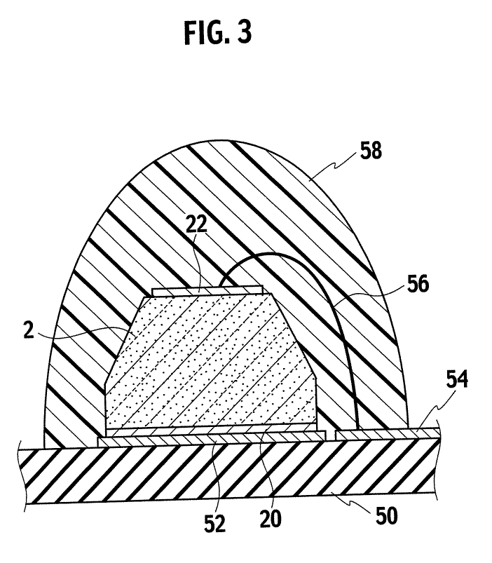

As shown in FIG. 3, the semiconductor light emitting device is molded with a resin member in order to increase light extraction efficiency. For example, the LED chip (20, 2, 22) is placed so that the first electrode 20 is electrically connected to a first pad 52 on a mounting substrate 50. The second electrode 22 is connected to a second pad 54 on the mounting substrate 50 through a bonding wire 56 and the like. A dome-shaped resin member 58 is formed on the mounting substrate 50 so as to cover the LED chip (20, 2, 22). For the resin member 58, a transparent resin, such as a silicon resin, and an epoxy resin, having a refractive index between about 1.4 and about 1.8 may be used. Hereafter, unless otherwise specified, the resin member 58 is omitted from a description of the drawing.

In a cross section perpendicular to the back surface of the semiconductor substrate 10, respective side surfaces 40a, 40b, 40c and 40d of the semiconductor substrate 10 are bevel planes having bevel angles Θ to planes parallel to the back surface of the semiconductor substrate 10. The distance between the active layer 14 and the first electrode 20 is denoted as “d”.

The distance d corresponds to a physical thickness of the contact layer 18 provided between the active layer 14 and the first electrode 20. For example, the refractive index of the semiconductor material GaN of the contact layer 18 is denoted by “n” and a center wavelength of light emitted from the active layer 14 is denoted by “λ”. The distance d is provided so that a value of (n×d/λ) is about 0.4. Specifically, when the wavelength λ is about 450 nm and the refractive index of GaN for the wavelength λ is about 2.47, the distance d is about 72 nm. In addition, the product of (n×d) is an optical thickness for the contact layer 18.

Furthermore, the bevel angles Θ of the side surfaces 40a to 40d of the semiconductor substrate 10 are about 57 degrees. The lights emitted from the active layer 14 are extracted from the inclined side surfaces 40a to 40d and enter the external resin member. As shown in FIG. 2, a light Lb emitted towards the contact layer 18 from the active layer 14 is reflected by the first electrode 20 and interferes with a light La emitted towards the semiconductor substrate 10 from the active layer 14.

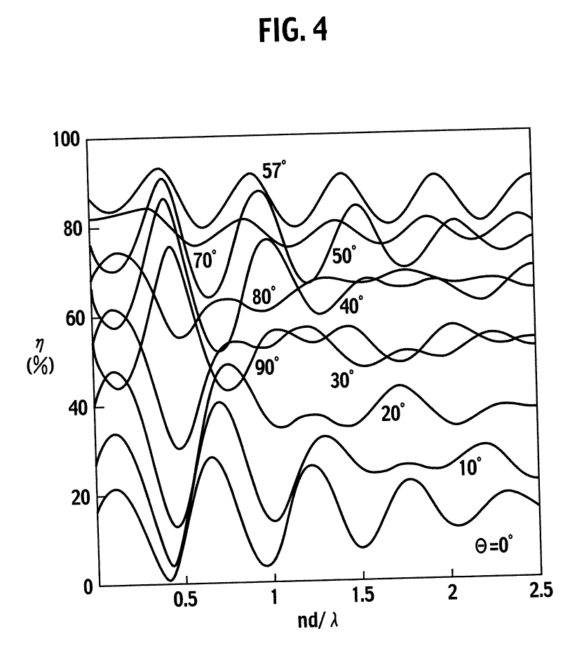

A light extraction efficiency η of the extracted light, in the resin member 58 from the semiconductor layer 2 shown in FIG. 3, depends on the distance d and the bevel angle Θ. FIG. 4 shows the relations between the light extraction efficiency η and the distance d, calculated by changing the bevel angle Θ. The light extraction efficiency η is increased or decreased as a function of (n×d/λ), more specifically, as a function of the distance d.

In the calculation of the light extraction efficiencyη, interference effect between the light La emitted towards the semiconductor substrate 10 from the active layer 14 and the light Lb reflected from the first electrode 20 should be considered. Here, Ag is used as the first electrode 20. A complex refractive index of Ag is about (0.055-2.42i). When the lights La, Lb are superimposed with each other, the respective lights La, Lb may be intensified or attenuated by each other due to a constructive or a destructive interference. Thus, the light extraction efficiency η is varied depending on the distance d. Additionally, the light extraction efficiency η is also varied depending on an angle of Θ light extraction plane. As shown in FIG. 4, when the bevel angle Θ is about 57 degrees and (n×d/λ) is about 0.4, the light extraction efficiency η is maximized. Additionally, in order to ensure the interference effect with the reflection light from the first electrode 20, it is desirable to provide the value of (n×d/λ) in a range of about 0.3 and about 0.5.

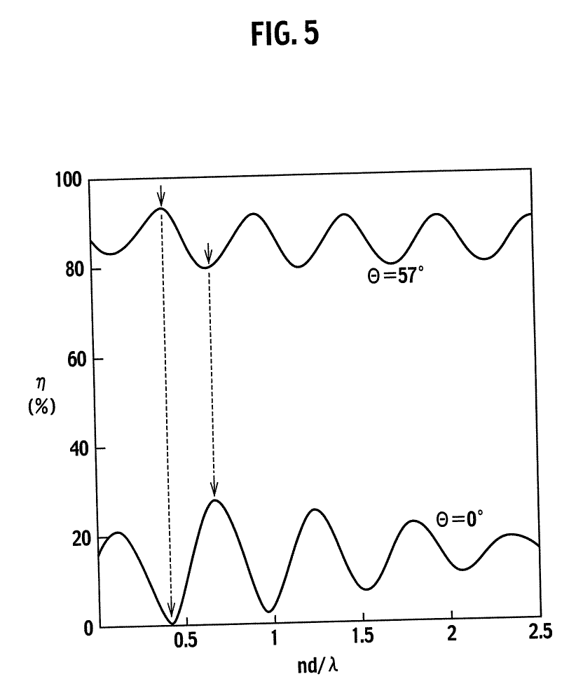

FIG. 5 shows a comparison of the light extraction efficiency Θ for the bevel angle Θ of 0 degree and about 57, degrees. Here, the bevel angle Θ of 0 degree corresponds to a case where the light is extracted from the back surface of the semiconductor substrate 10, and the bevel angle Θ of about 57 degrees corresponds to a case where the light extraction efficiency η is maximized. Note that for the bevel angles Θ of 0 degree and about 57 degrees, the maximum and the minimum light extraction efficiency η are substantially inversed.

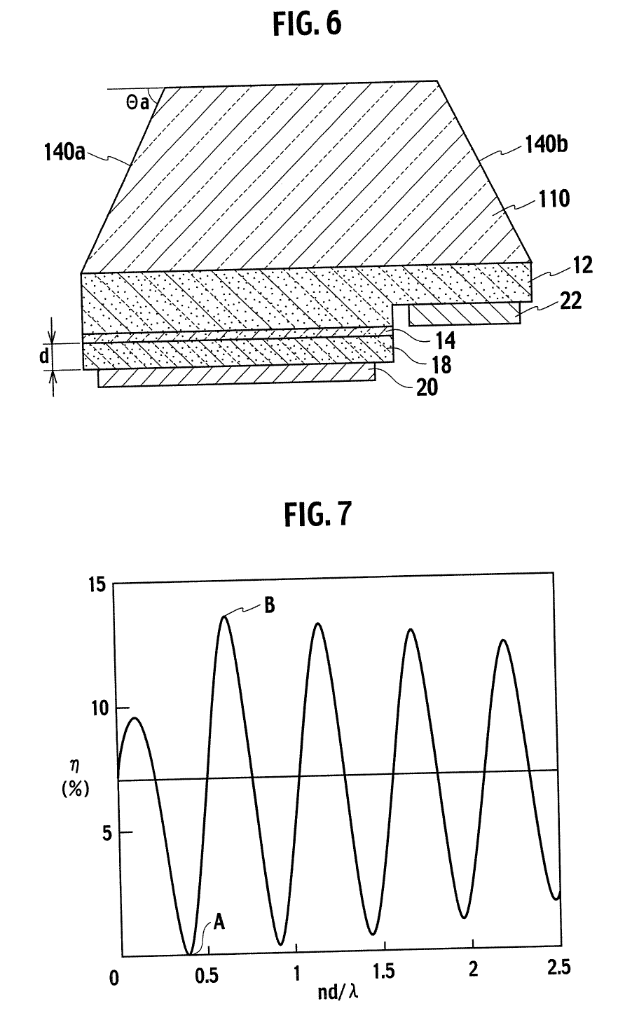

For an LED, which is manufactured by using a sapphire substrate, as a comparative example, the light extraction efficiency has been calculated. As shown in FIG. 6, the LED of the comparative example contains a sapphire substrate 110, a buffer layer 12, an active layer 14, a contact layer 18, a first electrode 20 and a second electrode 22. The second electrode 22 is provided on the buffer layer 12 on the same side of the first electrode 20 with respect to the sapphire substrate 110. Side surfaces 140a, 140b of the sapphire substrate 110 are inclined with a bevel angle Θa with respect to a plane parallel to a surface of the sapphire substrate 110. The distance between the active layer 14 and the first electrode 20 is “d”.

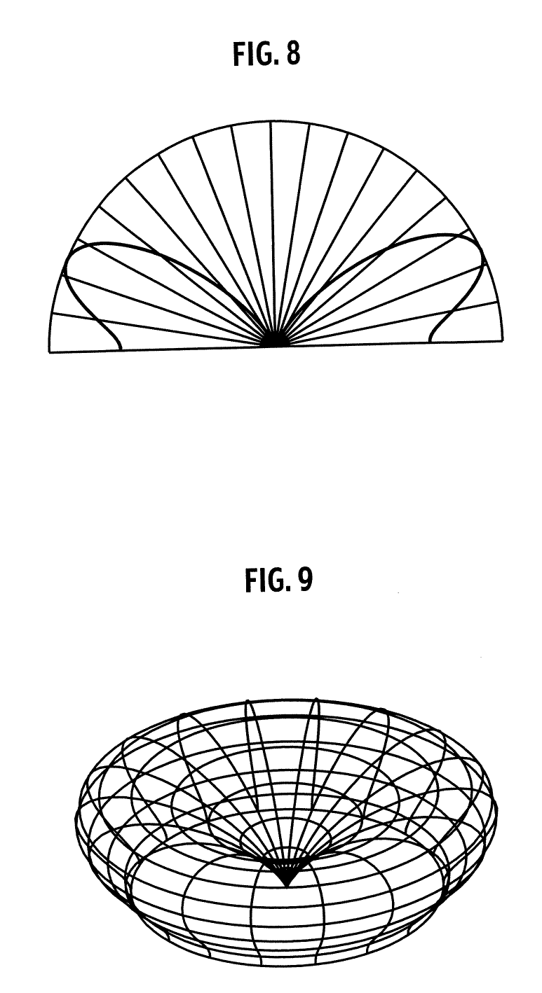

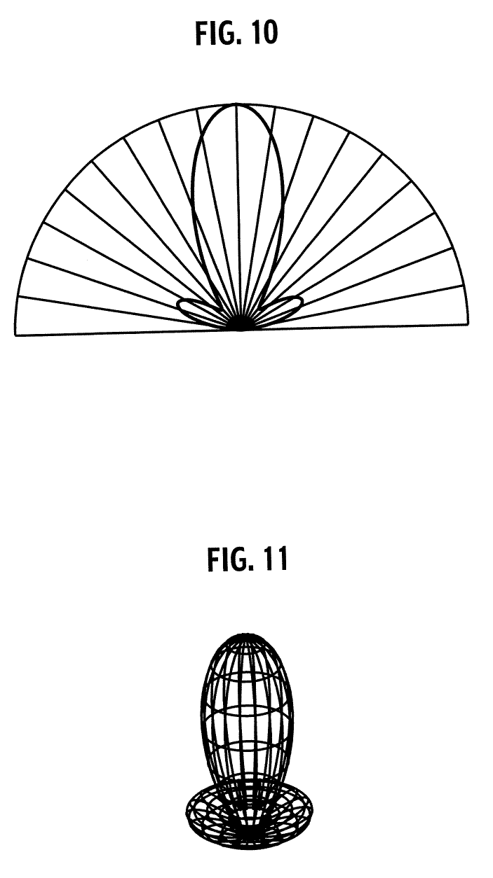

As shown in FIG. 7, even in the comparative example, the light extraction efficiency η of a light extracted into the air from the sapphire substrate 110 is increased or decreased depending on the distance d between the active layer 14 and the first electrode 20. In the calculation for the comparative example, consideration is given to the interference effect of the lights that are totally reflected by an interface between the buffer layer 12 of the GaN layer and the sapphire substrate 110, and an interface between the sapphire substrate 110 and the air. Light distributions radiated to the sapphire substrate 110 and the air based on a condition A shown in FIG. 7, in which the light extraction efficiency η is minimized, are shown in FIGS. 8, 9 and FIGS. 10, 11, respectively. As shown in FIGS. 8, 9, for the condition A, the light distribution in a vertical direction in the sapphire substrate 110 is reduced, and the light distribution in an oblique direction of about 65 degrees is intensified. In the case of such light distribution, at the interfaces between the buffer layer 12 and the sapphire substrate 110, and between the sapphire substrate 110 and the air, most of the lights will be total reflected. As a result, as shown in FIGS. 10, 11, the light emitted to the air is limited substantially only in the vertical direction.

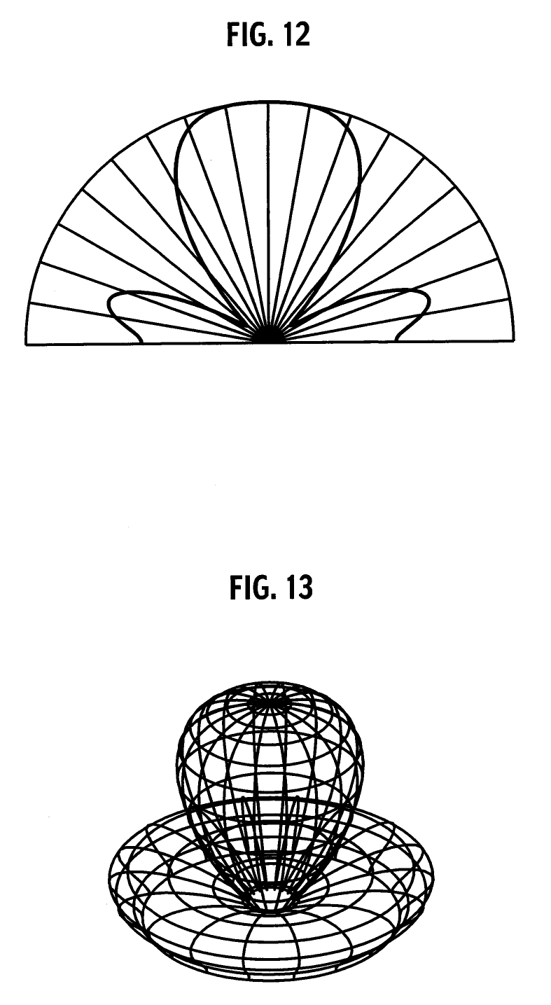

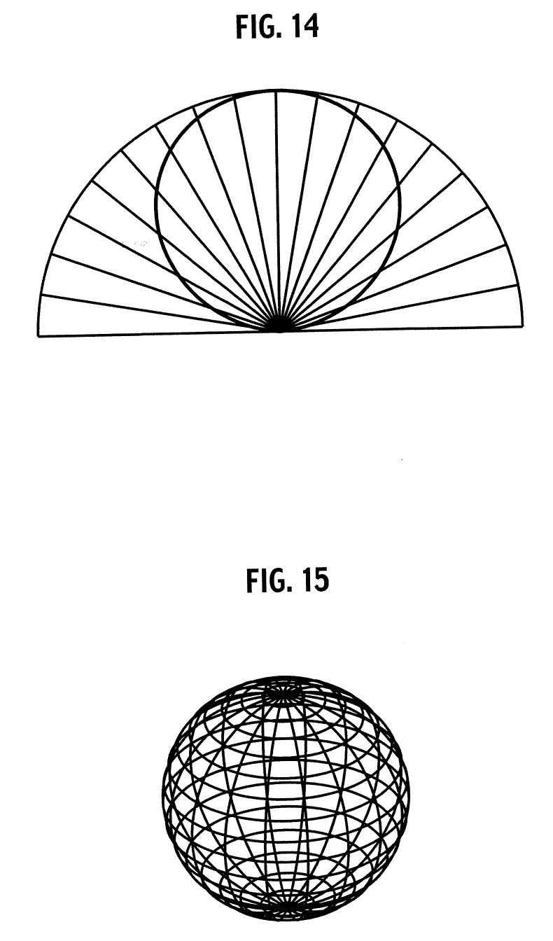

On the other hand, light distributions radiated to the sapphire substrate 110 and the air under a condition B shown in FIG. 7, in which the light extraction efficiency η is maximized, are shown in FIGS. 12, 13 and FIGS. 14, 15, respectively. As shown in FIGS. 12, 13, under the condition B (maximized light extraction efficiency η), the light distribution in the vertical direction in the sapphire substrate 110 is intensified. As a result, as shown in FIGS. 14, 15, the light can be emitted from the entire sapphire substrate 110.

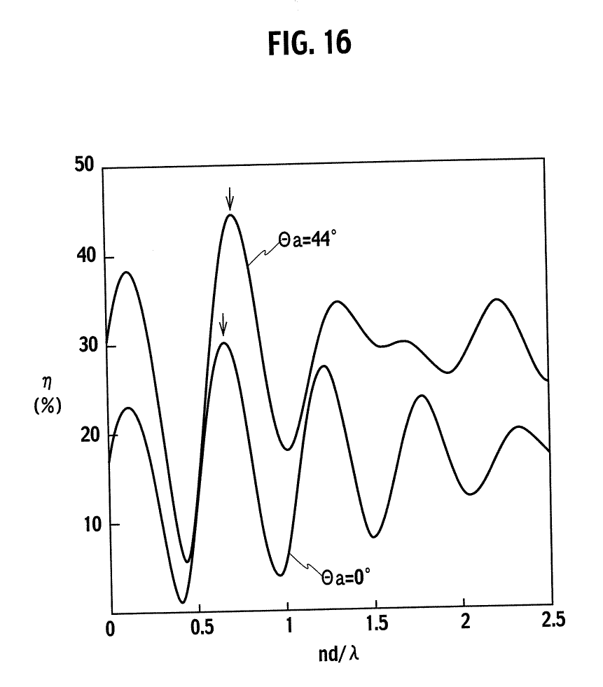

The value of (n×d/λ) corresponding to the condition B is not changed so much, even when the LED is surrounded by the resin instead of air, and even when the light is extracted from the inclined side surfaces of the sapphire substrate but not in the vertical direction. This is because, when the light is extracted from the inclined side surfaces of the sapphire substrate, the operational effect of the total reflection at the interface between the GaN layer and the sapphire substrate is still achieved. Calculation results of the light extraction efficiency n of the LED surrounded by the resin are shown in FIG. 16, in the cases for extracting the light from the plane parallel to the interface between the buffer layer 12 and the sapphire substrate 110, i.e. the bevel angle Θa is 0 degree, and for extracting the light from the side surfaces of the sapphire substrate 110 where the bevel angle Θa is about 44 degrees. In both cases, the light extraction efficiency η is maximized when the value of (n×d/λ) is about 0.7.

Furthermore, in the comparative example, a sapphire substrate 110 is used. Thus, a flip-chip structure in which the first electrode 20 and the second electrode 22 are formed on the same side may be used. Since levels of the surfaces of the first and second electrodes 20, 22 are different, package assembly may be difficult. Moreover, it is impossible to flow a current vertically between the first and second electrodes 20, 22. Thus, the series resistance may be increased.

As shown in FIG. 16, in the comparative example, the lights emitted in the vertical direction and in the oblique direction are maximized or minimized for approximately the same value of (n×d/λ). Inversely, as shown in FIG. 5, when one of the lights emitted in the vertical direction and in the oblique direction, with the approximately same value of (n×d/λ), is maximized, then the other is minimized. Thus, a design manual is perfectly different (opposite) between the case of using a sapphire substrate and the case of using a GaN substrate. That is, the design manual for the sapphire substrate cannot be used for the GaN substrate.

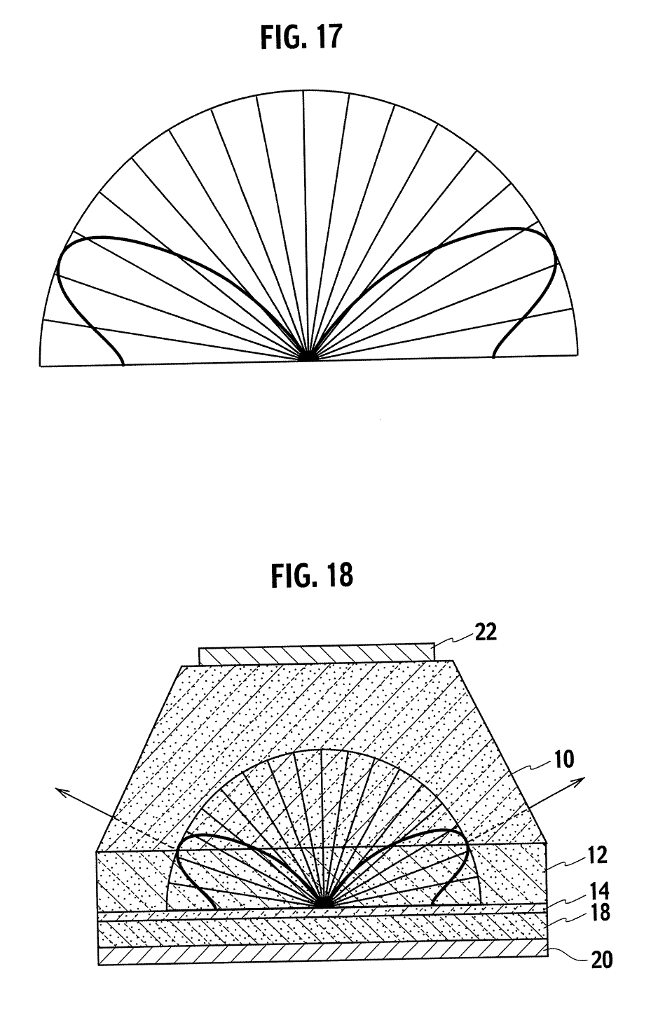

FIG. 17 shows a light distribution characteristic in the GaN semiconductor substrate 10 when (n×d/λ) is about 0.4. The light distribution in the semiconductor substrate 10 is quite different from the sapphire substrate 110 shown in FIG. 12 in that the light intensity in the vertical direction is reduced and the light intensity in the oblique direction is intensified. As shown in FIG. 18, the light extraction efficiency η when the light is extracted from the inclined side surfaces is greater than the case when the light is extracted from the horizontal plane. Therefore, as shown in FIG. 1, the structure having the inclined sides 40a to 40d maximizes the light extraction efficiency η. Also, since it is not required to extract the light from the back surface of the semiconductor substrate 10, the electrode can be placed on the back surface of the semiconductor substrate 10. Accordingly, in the semiconductor light emitting device according to the embodiment of the present invention, it is possible to decrease series resistance, and to increase the light extraction efficiency.

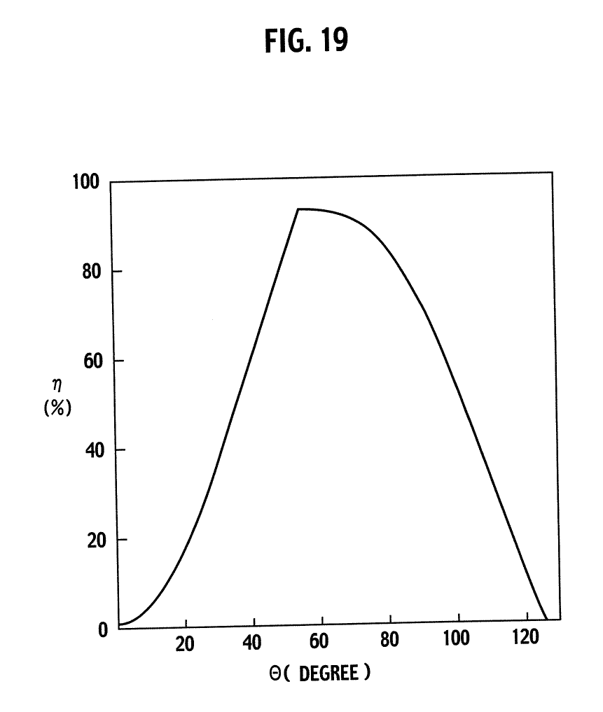

FIG. 19 shows a dependence of the light extraction efficiency η on the bevel angle Θ, when (n×d/λ) is about 0.4. As mentioned above, when the bevel angle Θ is about 57 degrees, the light extraction efficiency η is maximized. As shown in FIG. 19, a range of the bevel angle Θ in which the higher light extraction efficiency η is provided is not so narrow. For example, a range of the bevel angle Θ in which the light extraction efficiency η is about 80% or more, is between about 50 degrees and about 80 degrees. Also, a light extraction efficiency η of about 70% or more can be provided in a range of about 45 degrees and less than about 90 degrees.

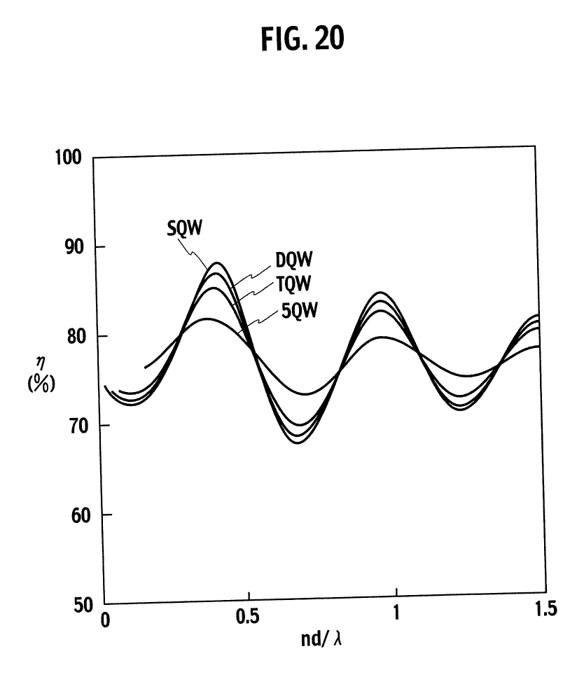

In the above-described description, the thickness of the active layer 14 is ignored in the calculation. Actually, when a multiple quantum well (MQW) layer is used, the light extraction efficiency η is varied depending on the position of the active layer. Thus, as for an average light extraction efficiency η, it may differs from the value shown in FIG. 4. FIG. 20 shows calculation results for respective light extraction efficiencies η of a single quantum well (SQW) layer, a double quantum well (DQW) layer, a triple quantum well (TQW) layer and a quintuple quantum well (5QW) layer. As the number of quantum wells is increased, the effect of the interference with the reflection light from the first electrode 20 is decreased. Until the number of quantum wells is about three, the difference between the maximum and minimum of light extraction efficiencies η is clearly seen, and it is possible to ensure the interference effect.

In addition, the semiconductor light emitting device shown in FIG. 2 includes the semiconductor substrate 10 and the buffer layer 12 as the first semiconductor layer, and the contact layer 18 as the second semiconductor layer. However, the first semiconductor layer may include a plurality of semiconductor layers, such as a guide layer, a clad layer and the like. The second semiconductor layer may include a plurality of semiconductor layers, such as a guide layer, an electron overflow preventing layer, a clad layer and the like.

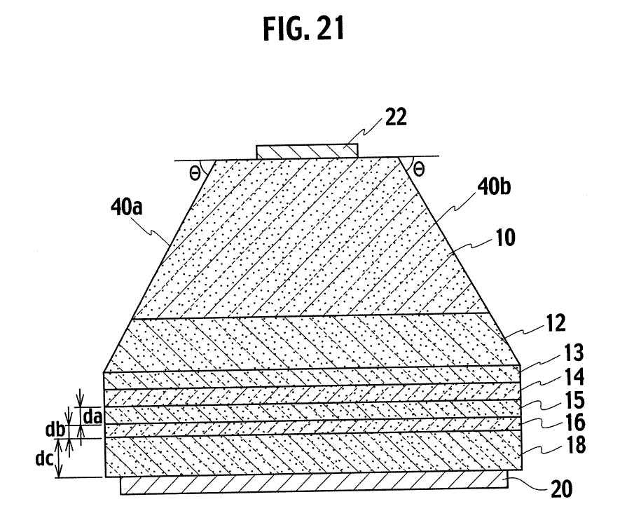

For example, as shown in FIG. 21, a first semiconductor layer (10, 12 and 13) includes an n-type GaN semiconductor substrate 10, an n-type GaN buffer layer 12 and an n-type GaN guide layer 13. A second semiconductor layer (15, 16 and 18) includes a p-type InGaN guide layer 15, a p-type GaAlN electron overflow preventing layer 16 and a p-type GaN contact layer 18. The electron overflow preventing layer 16 is used to prevent overflow of electrons.

For example, the physical thickness and refractive index of the guide layer 15 are denoted as “da”, “na”, and the physical thickness and refractive index of the electron overflow preventing layer 16 are denoted as “db”, “nb”, and the physical thickness and refractive index of the contact layer 18 are denoted as “dc”, “nc”. An optical thickness of the second semiconductor layer (15, 16 and 18) is represented by (na×da+nb×db+nc×dc). An effective refractive index n_{eff} of the second semiconductor layer (15, 16 and 18) is defined as {(na×da+nb×db+nc×dc)/(da+db+dc)}. By using a distance (da+db+dc) between the active layer 14 and the first electrode 20 and the effective refractive index n_{eff}, it is possible to obtain a result similar to the dependence of the light extraction efficiency η on (n×d/λ), as shown in FIG. 14.

Moreover, the second semiconductor layer may include a plurality of semiconductor layers, which includes i-th semiconductor layer of the semiconductor layers having a physical thickness dᵢ and a refractive index nᵢ Here, i=1 to k, where k is an integer equal to or greater than 2. In such case, the thickness d between the active layer and the first electrode is defined by (d₁+d₂+ . . . +dₖ). An optical thickness of the second semiconductor layer is represented by (n₁×d₁+n₂×d₂+. . . +nₖ×dₖ), and an effective refractive index n_{eff} of the second semiconductor layer is defined as {(n₁×d₁+n₂×d₂+ . . . +nₖ×dₖ)/(d₁+d₂⁺. . . +dₖ)}. Thus, it is desirable to satisfy a condition of

0.3≦(n₁×d₁+n₂×d₂+ . . . +nₖ×dₖ)/μ≦0.5,

in order to ensure the interference effect with the reflection light from the first electrode 20.

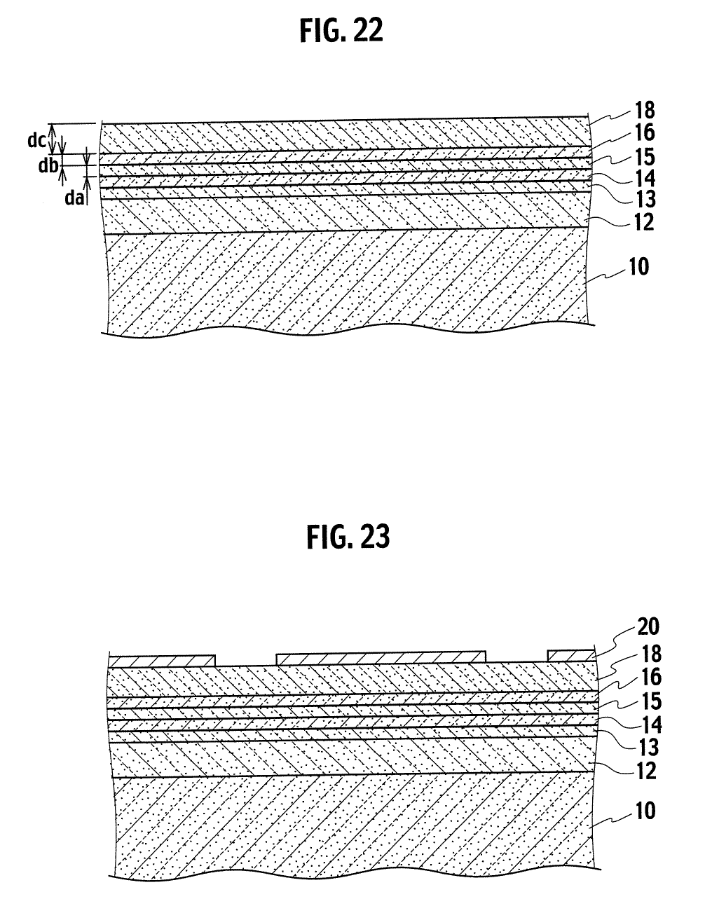

A method for manufacturing a semiconductor light emitting device according to the embodiment of the present invention will be described below by using cross sectional views shown in FIGS. 22 to 25. In addition, the semiconductor light emitting device shown in FIG. 21 is used in the description.

As shown in FIG. 22, an n-type GaN buffer layer 12, an n-type GaN guide layer 13, an active layer 14, a p-type In_{0.005}Ga_{0.95}N guide layer 15, a p-type Ga_{0.8}Al_{0.2} electron overflow preventing layer 16 and a p-type GaN contact layer 18 are sequentially grown on a front surface of an n-type GaN semiconductor substrate 10 by metal-organic chemical vapor deposition (MOCVD) and the like.

The buffer layer 12 is doped with an n-type impurity, such as silicon (Si), germanium (Ge) and the like, at an impurity concentration of about 2×10¹⁸ cm⁻³. The guide layer 13 is grown at a film thickness of about 0.1 μm and doped with the n-type impurity at an impurity concentration of about 1×10¹⁸ cm⁻³. For the guide layer 13, the n-type In_{0.01}Ga_{0.99}N may be used. The growth temperature of the buffer layer 12 and the guide layer 13 is, for example, about 1000° C. to about 1100° C.

As for the active layer 14, an SQW layer is used, in which a quantum well and barrier layers sandwiching the quantum well are laminated. The quantum well layer is an undoped In_{0.2}Ga_{0.8}N having a film thickness of about 3.5 nm. Each barrier layer is an undoped In_{0.01}Ga_{0.99}N having a film thickness of about 7 nm. Alternatively, an MQW layer, in which quantum wells and barrier layers are alternately laminated, may be used for the active layer 14. The growth temperature of the active layer 14 is about 700° C. to about 800° C.

The guide layer 15 is grown with a film thickness da of about 40 nm. The electron overflow preventing layer 16 is grown with a film thickness db of about 10 nm and is doped with a p-type impurity, such as magnesium (Mg), zinc (Zn) and the like, with an impurity concentration between about 4×10¹⁸ cm⁻³ and about 1×10¹⁸ cm⁻³. The contact layer 18 is grown with a film thickness dc of about 25 nm, and doped with a p-type impurity, such as Mg, having ant an impurity concentration of about 1×10¹⁹ cm⁻³. The growth temperatures of the guide layer 15, the current block layer 16 and the contact layer 18 are about 1000° C. to about 1100° C.

As shown in FIG. 23, using photolithography, vacuum evaporation, and the like, a first electrode 20 is formed on a surface of the contact layer 18. For the first electrode 20, a high reflectivity metal film, such as Ag, and an alloy including Ag may be used.

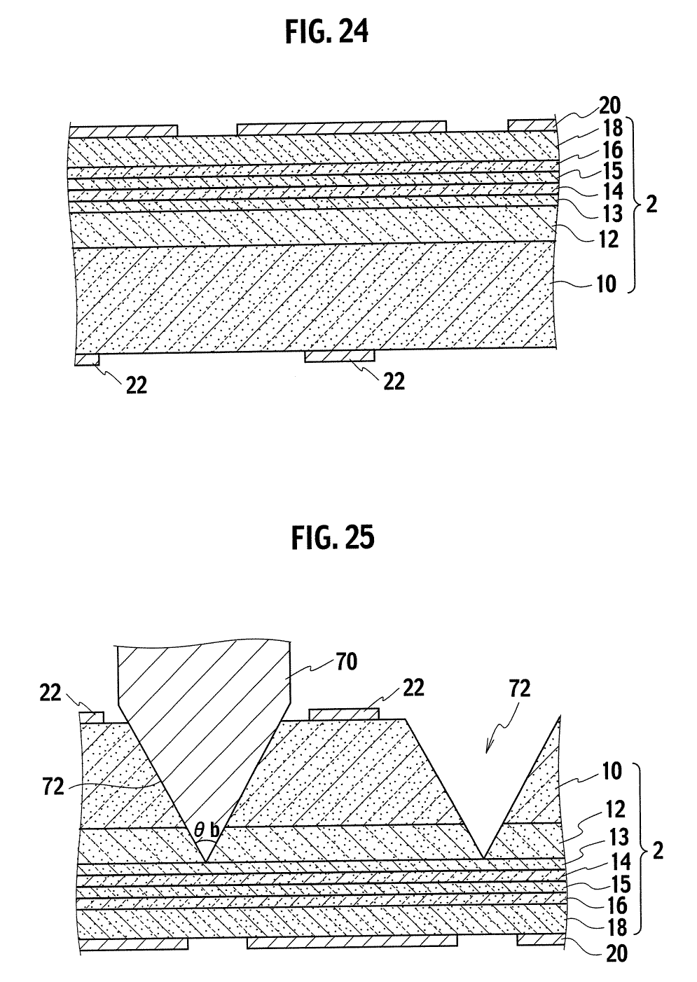

As shown in FIG. 24, the semiconductor substrate 10 is polished on a back surface, and a thickness of the semiconductor layer 2 is adjusted within a range of about 100 μm to about 350 μm. Thereafter, using photolithography or electron beam lithography, vacuum evaporation and the like, a second electrode 22 is formed on the polished back surface of the semiconductor substrate 10. For the second electrode 22, a Ti/Pt/Au laminated metal film is used. For example, thicknesses of Ti, Pt, and Au are about 0.05 μm, about 0.05 μm, and about 1 μm, respectively.

As shown in FIG. 25, by using a blade 70, a groove 72 is formed on the back surface of the semiconductor substrate 10. A tip angle θb of the blade 70 is about 90 degrees or less, for example, about 46 degrees. The semiconductor layer 2 is cut into a plurality of chips by breaking the layer 2 along the groove 72. Each chip has a square shape or a rectangular shape of about 200 μm to about 1000 μm on a side. Thereafter, the chips are molded with a resin. Thus, a semiconductor light emitting device, shown in FIG. 3, is manufactured.

The distance between the active layer 14 and the first electrode 20 in the manufactured semiconductor light emitting device is (da+db+dc) as shown in FIG. 22. The refractive index na of the guide layer 15 is about 2.47, the refractive index nb of the current block layer 16 is about 2.42, and the refractive index nc of the contact layer 18 is about 2.47. The effective refractive index n_{eff} is about 2.46. An emission wavelength of the active layer 14 is about 450 nm. Therefore, the value of {n_{eff}×(da+db+dc)/λ} is about 0.4. Also, a bevel angle of a side surface of the groove 72 is about 57 degrees. As a result, the interference effect, as described above, due to the light reflected from the first electrode 20, can be achieved. Thus, it is possible to maximize the light extraction efficiency. Also, the first and second electrodes 20, 22 face each other across the semiconductor layer 2. Hence, series resistance between the first and second electrodes 20, 22 may be decreased. Moreover, package assembly, such as resin molding and the like, may be easily implemented.

### OTHER EMBODIMENTS

In the embodiment of the present invention, a light emitting device using a nitride based semiconductor is described. However, a light emitting device using another group III-V compound semiconductor or a group II-VI compound semiconductor, such as zinc selenide (ZnSe), zinc oxide (ZnO) and the like may be used.

Additionally, various kind of semiconductor layers are grown by MOCVD. However, the growth method for the semiconductor layer is not so limited. For example, it is possible to grow the semiconductor layers by molecular beam epitaxy (MBE) and the like.

Various modifications will become possible for those skilled in the art after storing the teachings of the present disclosure without departing from the scope thereof.

What is claimed is:

1. A semiconductor light emitting device, comprising:
an active layer radiating a light having a wavelength λ;
a first semiconductor layer of a first conductivity type provided on the active layer, the first semiconductor layer having a first principal surface, a second principal surface and side surfaces, the first principal surface in contact with the active layer, the second principal surface facing the first principal surface, and the side surfaces connected to the second principal surface, each of the side surfaces having a bevel angle in a range from about 45 degrees to less than 90 degrees with respect to the second principal surface;
a second semiconductor layer of a second conductivity type provided under the active layer; and
a first electrode provided under the second semiconductor layer,
wherein a distance d between the active layer and the first electrode depends on the wavelength λ and a refractive index n of the second semiconductor layer.

2. The semiconductor light emitting device of claim 1, wherein the distance d satisfies a condition of
0.3≦n×d/λ≦0.5.

3. The semiconductor light emitting device of claim 1, wherein the second semiconductor layer includes a plurality of semiconductor layers, and for i-th semiconductor layer of the semiconductor layers having a thickness dᵢ and a refractive index nᵢ (i=1 to k, where k is an integer equal to or greater than 2), satisfies a condition of
0.3≦(n₁×d₁+n₂×d₂+ . . . +nₖ×dₖ)/λ≦0.5,
where d=d₁+d₂⁺. . . +dₖ.

4. The semiconductor light emitting device of claim 1, wherein the first electrode is made of silver or an alloy including silver.

5. The semiconductor light emitting device of claim 1, wherein the bevel angle is in a range of about 50 degrees to about 80 degrees.

6. The semiconductor light emitting device of claim 1, wherein the second semiconductor layer includes a gallium nitride layer.

7. The semiconductor light emitting device of claim 1, wherein the active layer includes a quantum well layer.

8. The semiconductor light emitting device of claim 1, further comprising, a second electrode provided on the second principal surface.

9. The semiconductor light emitting device of claim 7, wherein the quantum well layer includes at least three quantum wells.

10. A method for manufacturing a semiconductor light emitting device, comprising:
growing an active layer on a front surface of a first semiconductor layer having a first conductivity type;
growing a second semiconductor layer of a second conductivity type on the active layer;
forming a first electrode on the second semiconductor layer;
forming a second electrode on a back surface of the first semiconductor layer; and
dividing the first and second semiconductor layers into a chip having side surfaces, each of the side surfaces having a bevel angle in a range from about 45 degrees to less than 90 degrees with respect to the back surface,
wherein a distance between the active layer and the first electrode depends on a wavelength λ and a refractive index n of the second semiconductor layer.

11. The method of claim 10, wherein the distance d satisfies a condition of
0.3≦n×d/λ≦0.5.

12. The method of claim 10, wherein the second semiconductor layer includes a plurality of semiconductor layers, and for i-th semiconductor layer of the semiconductor layers having a thickness dᵢ and a refractive index nᵢ (i=1 to k, where k is an integer equal to or more than 2), satisfies a condition of
0.3≦(n₁×d₁+n₂×d₂+ . . . +nₖ×dₖ)/λ≦0.5,
where d=d₁+d₂+ . . . +dₖ.

13. The method of claim 10, wherein the first electrode is formed by depositing silver or an alloy including silver.

14. The method of claim 10, wherein the bevel angle is in a range from about 50 degrees to about 80 degrees.

15. The method of claim 10, wherein the second semiconductor layer includes a gallium nitride layer.

16. The method of claim 10, wherein the active layer includes a quantum well layer.

17. The method of claim 16, wherein of the quantum well layer includes at least three quantum wells.
